(19) United States
(12) Patent Application Publication
(10) Pub. No.: US 2008/0070423 A1
(43) Pub. Date: Mar. 20, 2008

(54) Buried seed one-shot interlevel crystallization

(76) Inventors: Mark A. Crowder, Portland, OR (US); Apostolos T. Voutsas, Portland, OR (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(21) Appl. No.: 11/521,996

(22) Filed: Sep. 15, 2006

(51) Int. Cl. H01L 21/00

(52) U.S. Cl. 438/795

(57) ABSTRACT

A method is provided for crystallizing a semiconductor film using a buried seed one-shot interlevel crystallization process. The method forms a first semiconductor film having a crystallographic structure, overlying a transparent substrate. An insulator layer is formed overlying the first semiconductor film, and an opening is formed in the insulator layer, which exposes a portion of a first semiconductor film top surface. Then, a second semiconductor film with an amorphous structure is formed overlying the insulator layer. Typically, the first and second semiconductor films are Si, and the insulator is often an oxide or nitride. The second semiconductor film is laser annealed. In one aspect, the annealing is accomplished with a single laser shot. In response to the laser annealing, the second semiconductor film is completely melted and the first semiconductor film is partially melted. Using unmelted first semiconductor film as a seed, the second semiconductor film is crystallized.

### 1. FIELD OF THE INVENTION

This invention generally relates to integrated circuit (IC) fabrication and, more particularly, to a dual-gate thin-film transistor (DG-TFT) fabricated process using a buried seed interlevel crystallization method.

### 2. DESCRIPTION OF THE RELATED ART

For hybrid continuous grain silicon (CGS) processing of silicon (Si) thin-films for TFT applications, the “1-shot” process is a high-throughput scheme that can provide location control of the grain boundaries in the crystalline film. A laser pulse is typical referred to as a “shot”, and a 1-shot process uses a single laser pulse to anneal a film. There are two main implementations of this approach that affect the resulting microstructure—either pre-patterning the Si islands prior to crystallization, or not. In either case, the location control is induced by fully melting the Si film in all areas except where a pre-positioned seed is desired, to begin the crystallization of the supercooled melt. Typically, this seed is placed by first encapsulating the Si layer (either pre-patterned or non-patterned) with a 500 Å SiO₂ cap layer, depositing a sufficiently thick Si layer (approximately 2,000 Å), and then patterning the Si layer to leave behind dots or lines that will shadow the excimer laser radiation from the underlying Si active layer. The dots or lines have to be large enough to keep a sufficiently wide region of the Si underlayer from being irradiated, in order to account for lateral heat diffusion. Typical widths are on the order of 3-4 microns (μm). When the surrounding molten Si begins to cool below the equilibrium temperature, the seed initiates lateral growth into the surrounding regions.

FIG. 1 is a perspective drawing depicting a pre-patterned Si active layer with a shadow Si layer (dot) for a “1-shot” location control crystallization scheme (prior art). FIG. 1 shows a 70° tilted sample with a pre-patterned Si island and a cap Si layer to induce lateral growth. Upon irradiation, the seed initiates growth from under the shadow dot and lateral growth then proceeds around the spiral and into the remainder of the Si island.

In many embodiments of the above-described approach, the dot must eventually be removed, which can be problematic for subsequent TFT fabrication steps (e.g., implantation, contact hole formation, and planarity). Removal of the dot requires either a controlled dry etch of the Si shadow layer, a wet etch in TMAH, or (for non-patterned Si active layers) an etch in dilute HF to undercut the lines and dots and cause them to lift off.

A better approach would be to seed the lateral growth via a means that can be left in place following the crystallization and that will not interfere with subsequent processing steps.

### SUMMARY OF THE INVENTION

A “1-shot” location control crystallization scheme can be enhanced if a predetermined region of the Si active layer can be left in contact with an area of solid (i.e., non-melted) Si that can act as a seed for lateral growth. For a variety of reasons, including better compatibility with 3D architectures and improved throughput, it is desirable to crystallize greater areas with a single shot. The conventional directional solidification approach is no longer sufficient for current designs which utilize the co-integration of various 3D architectures (e.g., back-gate, planar, and dual-gate TFTs). To better enable the crystallization of 3D structures, the present invention uses the back-gate as a means to seed the lateral growth and control the placement of the grain boundaries relative to the active channel of the TFTs.

Accordingly, a method is provided for crystallizing a semiconductor film using a buried seed one-shot interlevel crystallization process. The method forms a first semiconductor film having a crystallographic structure, overlying a transparent substrate. An insulator layer is formed overlying the first semiconductor film, and an opening is formed in the insulator layer, which exposes a portion of a first semiconductor film top surface. Then, a second semiconductor film with an amorphous structure is formed overlying the insulator layer. Typically, the first and second semiconductor films are Si, and the insulator is often an oxide or nitride. The second semiconductor film is laser annealed. In one aspect, the annealing is accomplished with a single laser shot. In response to the laser annealing, the second semiconductor film is completely melted and the first semiconductor film is partially melted. Using unmelted first semiconductor film as a seed, the second semiconductor film is crystallized.

One aspect of the method includes preheating the substrate with at least one laser fluence pulse from a first laser source, prior to melting the second semiconductor film with at least one laser fluence pulse from a second laser source.

In one application, the first semiconductor film forms a bottom gate overlying the substrate, the insulator layer forms a bottom gate dielectric, and the second semiconductor layer forms an active Si layer. More specifically, the bottom gate has a first portion and a second portion, and a via is formed in the gate dielectric overlying the bottom gate first portion. The bottom gate first portion is partially melted by the annealing, and the bottom gate second portion is used as the seed for crystallizing the active Si layer.

Additional details of the above-described methods are provided below.

### BRIEF DESCRIPTION OF THE DRAWINGS

FIG. 1 is a perspective drawing depicting a pre-patterned Si active layer with a shadow Si layer (dot) for a “1-shot” location control crystallization scheme (prior art).

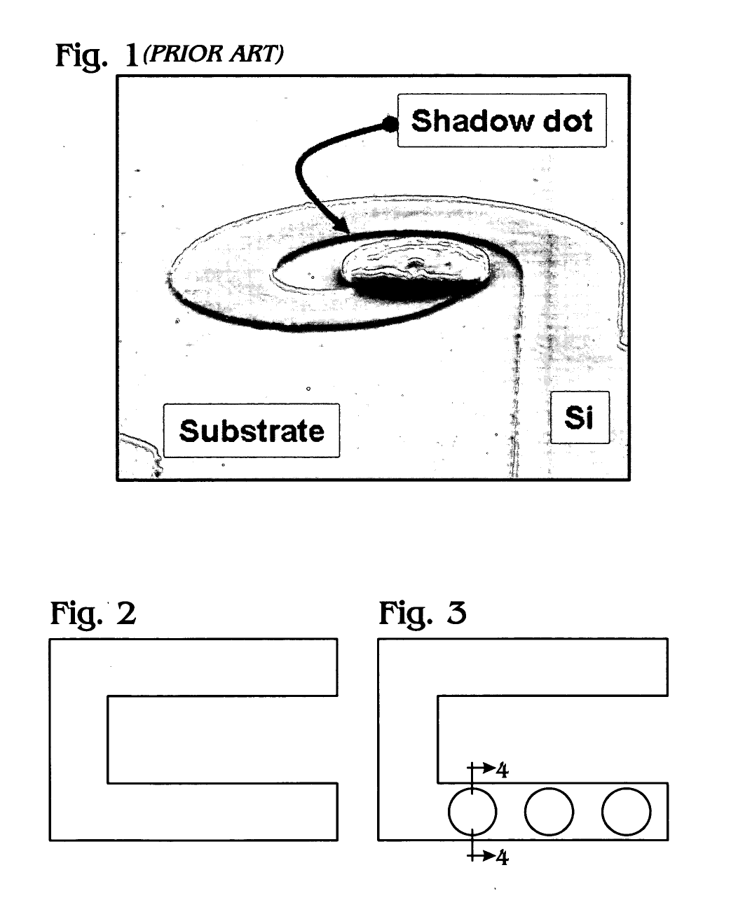

FIGS. 2 through 7 depict steps in the crystallization of a dual-gate TFT (DG-TFT) using a buried seed one-shot laser annealing process.

FIG. 8 is a flowchart illustrating a method for crystallizing a semiconductor film using a buried seed one-shot interlevel crystallization process.

FIG. 9 is a flowchart illustrating a DG-TFT fabrication method for seeding the crystallization of an active Si layer using vias to an underlying bottom gate.

### DETAILED DESCRIPTION

A “1-shot” location control crystallization scheme relies a predetermined region of the Si active layer being left in contact with a (non-melted) single-crystal region that acts as a seed for lateral growth. The crystallization of 3D structures in back-gate, planar, and dual-gate TFTs architectures is improved with the use of 1-shot laser annealing processes. An example is provided, below, of a back-gate that is used to seed the lateral growth and control the placement of the grain boundaries relative to the active channel of the TFTs.

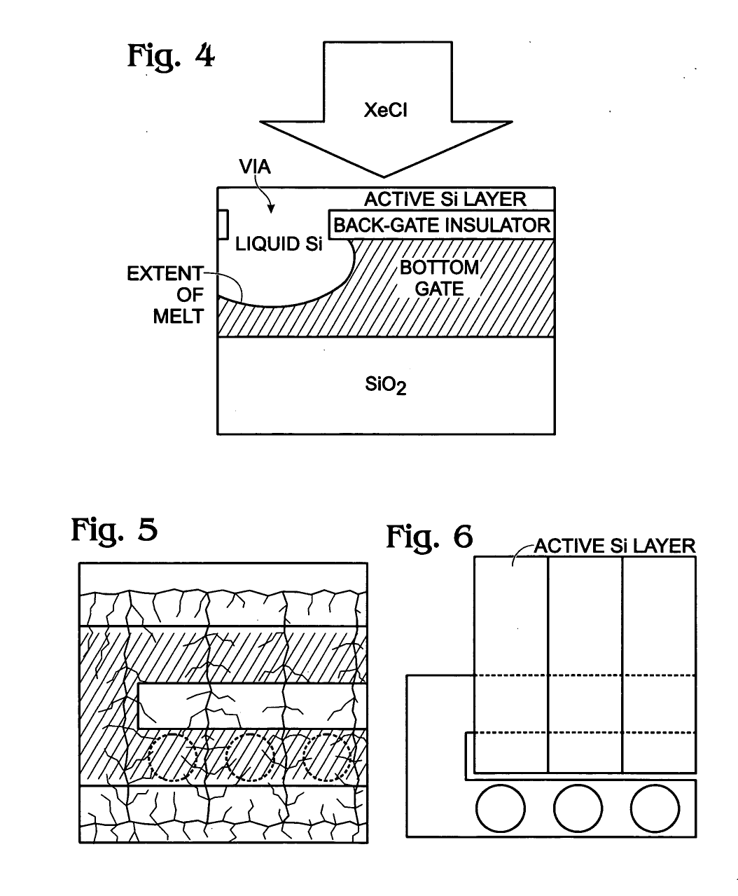

FIGS. 2 through 7 depict steps in the crystallization of a dual-gate TFT (DG-TFT) using a buried seed one-shot laser annealing process. Generally, a DG-TFT is a transistor with a bottom gate or back-gate, underlying a planar TFT structure, which includes source and drain regions, a channel, and a top gate. The back-gate is used to control the threshold voltage of the overlying planar TFT. Additional details of a DG-TFT can be found in a pending application entitled, DUAL-GATE TRANSISTOR DISPLAY, invented by Afentakis et al., Ser. No. 11/184,699, filed Jul. 18, 2005, which is incorporated herein by reference (Docket No. SLA8010).

FIG. 2 is a plan view of a bottom gate (back-gate). The bottom gate is doped, patterned, and then capped with back-gate insulator. Typically, the bottom gate is polycrystalline, or it may even have a single-crystal structure.

FIG. 3 is the bottom gate of FIG. 2 following the formation of contact holes, which have been opened through the back-gate insulator, to the bottom gate. An amorphous Si (a-Si) active layer is then deposited over back-gate insulator, making contact with the bottom gate through the via holes.

FIG. 4 is a partial cross-sectional view of the bottom gate of FIG. 3. A majority, if not all, of excimer fluence (represented by the arrow labeled “XeCl”) is absorbed by the active Si layer. A typical active Si layer may have a thickness on the order of 500 Å. Thermal conduction leads to the melt front extending through the via holes and partially melting the buried bottom gate electrode. The thermal mass of the bottom gate electrode may be of the order of four times the active Si layer thickness, resulting in a significant portion of the bottom gate remain solid. Upon cooling, vertical regrowth of solid material extends through the via hole, seeding LC (location controlled) lateral growth.

FIG. 5 is a plan view of the active Si layer following crystallization. The crystalline microstructure may be tailored to particular applications, for example, controlling the location of the grain boundaries relative to the active channel region of the TFTs. The figure shows circular regions in the center of crystal grains, where lateral growth has been initiated by seeds left in contact with molten Si. The relative position of bottom gate is shown in cross-hatch.

FIG. 6 is a plan view depicting the active Si layer after it has been patterned for use as the active channel of a TFT. Crystallization is carried out prior to patterning. Because the buried bottom gate electrode is covered with active Si, it is not been melted during irradiation. Patterning the active region breaks the (Si) contact with the active channel and the buried bottom gate electrode.

FIG. 7 is a plan view showing the final discrete device layout with 4 pads for contact to the source, drain, top gate, and back-gate. Devices may also be fabricated using the above-described approach without either the top or bottom gates, to provide planar or back-gate TFTs, in addition to the dual-gate TFT. More generally, the method is applicable to the crystallization of vertical structures using a “1-shot” non-pre-patterned location control crystallization scheme.

### Functional Description

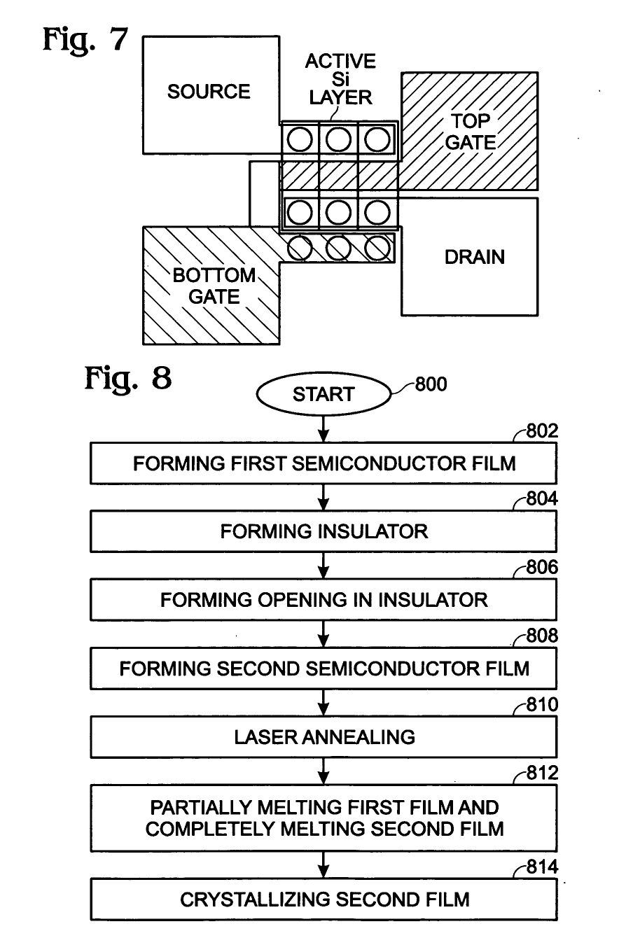

FIG. 8 is a flowchart illustrating a method for crystallizing a semiconductor film using a buried seed one-shot interlevel crystallization process. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. The method starts at Step 800.

Step 802 forms a first semiconductor film having a crystallographic structure, overlying a transparent substrate. For example, the transparent substrate may be glass, plastic, and quartz. Although the method can be used with any substrate material, laser annealing processes are commonly associated with these temperature-sensitive materials. Step 804 forms an insulator layer overlying the first semiconductor film. Step 806 forms an opening in the insulator layer, exposing a portion of a first semiconductor film top surface. Step 808 forms a second semiconductor film overlying the insulator layer, having an amorphous structure. Step 810 laser anneals the second semiconductor film. In response to the laser annealing, Step 812 completely melts the second semiconductor film and partially melts the first semiconductor film. Using unmelted first semiconductor film as a seed, Step 814 crystallizes the second semiconductor film.

In one aspect, forming an opening in the insulator layer in Step 804 includes forming an opening in a first location. Then, crystallizing the second semiconductor film in Step 814 includes controlling the grain boundaries of the crystallized second semiconductor film in response to the position of the first location. Returning briefly to FIGS. 5 and 6, it can be seen that the crystal grain boundaries formed in the Si active layer are positioned and formed with respect to the locations of the vias in the gate dielectric.

In one aspect, laser annealing the second semiconductor film in Step 810 includes preheating the substrate with at least one laser fluence pulse from a first laser source, prior to melting the second semiconductor film with at least one laser fluence pulse from a second laser source. For example, the substrate may be preheated with a carbon dioxide laser (CDL) pulse having a duration in a range of about 10 microseconds to 1 millisecond, and a repetition rate in a range of about 100 Hz to 50 KHz.

In another aspect, melting the second semiconductor film in Step 812 includes laser annealing the second semiconductor film with a single Excimer laser pulse. For example, laser annealing the second semiconductor film with the single Excimer laser pulse includes using a pulse duration in a range of about 30 nanoseconds (ns) to 300 ns.

The CO₂ laser fires first, to preheat the underlying SiO₂ substrate. At the end of the CDL pulse (typically 10 μs to 1 ms in length), the Excimer laser is fired such that the Si thin film directly above the preheated spot on the substrate is melted. These operations permit very localized heating of the material, to temperatures in excess of 900 to 1,000° C. This high local temperature, in turn, permits very long lateral growth lengths, in excess of 30 to 100 μm depending on the conditions. The process is called a “1-shot” process due to its ability to crystallize the entire Si film, which would make up an active portion of a device, in a single shot. The seeding structure is arranged to provide an optimal microstructure that is tailored to a particular active channel orientation, size, or other desired characteristic. Of course, the term “1-shot” only refers to the Excimer laser. The CO₂ laser can fire multiple times for each excimer laser pulse. The CDL can operate at frequencies up to 10 s of kHz, and for some conditions this is the typical operating condition. Additional details of this process can be found in U.S. Pat. No. 7,018,468, which is incorporated herein by reference.

Alternate preheating sources include a UV laser, such as an Excimer laser or frequency-tripled solid-state laser, or a visible laser, such as a frequency-doubled solid-state laser, as a laser annealing source. A XeCl laser at 308 nm or a KrF laser at 243 nm are possible candidates for the Excimer laser. Frequency-tripled solid-state lasers, such as tripled Nd-YAG lasers or tripled Nd-YVO₄ lasers, are also possible candidates for the UV laser. Frequency-doubled solid-state lasers, such as doubled Nd-YAG lasers operating at 532 nm or doubled Nd-YVO₄ lasers, are possible candidates for the visible laser.

In a different aspect, forming the first and second semiconductor films in Steps 802 and 808, respectively, includes forming first and second semiconductor films including Si. For example, films of (pure) Si and SiGe may be used, although the process likely has application to a broader range of thin-film process materials. The insulator layer formed in Step 804 is typically an oxide film, such as silicon dioxide, a nitride film, such as silicon nitride, an oxynitride, or even a high-k dielectric material.

In one aspect, forming the first semiconductor film in Step 802 includes forming a bottom gate overlying the substrate, and Step 804 forms a bottom gate dielectric. Forming the second semiconductor layer in Step 808 includes forming an active Si layer. In one aspect, the active Si layer formed in Step 808 has a thickness in a range of about 500 Å to 1,500 Å.

More specifically, forming the bottom gate in Step 802 includes forming a bottom gate with a first portion and a second portion. Step 806 forms a via in the gate dielectric overlying the bottom gate first portion. Partially melting the first semiconductor film in Step 812 includes melting the bottom gate first portion, and using unmelted first semiconductor film as a seed in Step 814 includes using the bottom gate second portion as the seed for crystallizing the active Si layer.

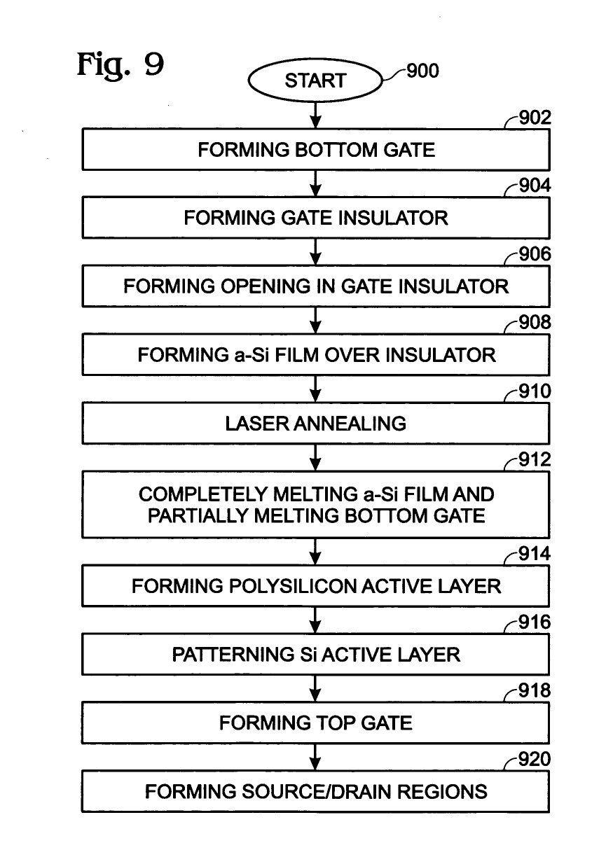

Subsequent to crystallizing the active Si layer, Step 816 patterns the active Si layer to remove the active Si layer overlying vias in the gate dielectric. Step 818 forms a top gate overlying the active Si layer, and Step 820 forms source/drain (S/D) regions in the active Si layer. Steps 816 through 820, associated with the DG-TFT fabrication process are not shown in this figure, since FIG. 9 is specifically dedicated to the DG-TFT process.

In one aspect, crystallizing the second semiconductor film includes laterally growing a crystal grain in the second semiconductor film having a length in the range of about 20 micrometers (μm) to 30 μm. With respect to the DG-TFT, the distance from the via hole to the unmelted portion of the bottom gate is typically less than the crystal grain length. The crystallographic orientation of the laterally grown grains can change or break down after a semi-characteristic length (about 15 μm for a 50 nm-thick Si film), and any benefits derived from controlling the orientation of the seed (i.e., placement near the via hole) are diminished.

FIG. 9 is a flowchart illustrating a DG-TFT fabrication method for seeding the crystallization of an active Si layer using vias to an underlying bottom gate. The method starts at Step 900. Step 902 forms a Si bottom gate having a polycrystalline structure, overlying a transparent substrate. Step 904 forms an insulator layer overlying the bottom gate. For example, an oxide or nitride insulator can be used. Step 906 forms an opening in the insulator layer, exposing a portion of a bottom gate top surface. Step 908 forms an amorphous Si film overlying the insulator layer. Step 910 laser anneals the amorphous Si film. In response to the laser annealing, Step 912 completely melts the amorphous Si film and partially melts the bottom gate. Using an unmelted bottom gate polycrystalline structure as a seed, Step 914 forms a polycrystalline Si active layer.

In one aspect, Step 910 preheats the substrate with at least one laser fluence pulse from a first laser source, prior to melting the amorphous Si film with at least one laser fluence pulse from a second laser source. In another aspect, Step 910 laser anneals with a single Excimer laser pulse.

In a different aspect, Step 902 forms a bottom gate with a first portion and a second portion, and Step 904 forms a via in a gate dielectric overlying the bottom gate first portion. Step 912 melts the bottom gate first portion, and Step 914 uses the bottom gate second portion as the seed for crystallizing the active Si layer.

Subsequent to forming the polycrystalline active Si layer, Step 916 patterns the active Si layer to remove the active Si layer overlying vias in the gate dielectric. Step 918 forms a top gate overlying the active Si layer. Step 920 forms source/drain (S/D) regions in the active Si layer.

Methods have been provided for using a buried seed to crystallize a semiconductor film. Process details, materials, and a DG-TFT structure have been used as examples to illustrate the invention. However, the invention is not limited to merely these examples. Other variations and embodiments of the invention will occur to those skilled in the art.

We claim:

1. A method for crystallizing a semiconductor film using a buried seed one-shot interlevel crystallization process, the method comprising:
forming a first semiconductor film having a crystallographic structure, overlying a transparent substrate;
forming an insulator layer overlying the first semiconductor film;
forming an opening in the insulator layer, exposing a portion of a first semiconductor film top surface;
forming a second semiconductor film overlying the insulator layer, having an amorphous structure;
laser annealing the second semiconductor film;
in response to the laser annealing, completely melting the second semiconductor film and partially melting the first semiconductor film; and,
using unmelted first semiconductor film as a seed, crystallizing the second semiconductor film.

2. The method of claim 1 wherein laser annealing the second semiconductor film includes preheating the substrate with at least one laser fluence pulse from a first laser source, prior to melting the second semiconductor film with at least one laser fluence pulse from a second laser source.

3. The method of claim 2 wherein preheating the substrate includes preheating the substrate with a carbon dioxide laser (CDL) pulse having a duration in a range of about 10 microseconds to 1 millisecond, and a repetition rate in a range of about 100 Hz to 50 KHz.

4. The method of claim 2 wherein melting the second semiconductor film includes laser annealing the second semiconductor film with a single Excimer laser pulse.

5. The method of claim 4 wherein laser annealing the second semiconductor film with the single Excimer laser pulse includes using a pulse duration in a range of about 30 nanoseconds (ns) to 300 ns.

6. The method of claim 1 wherein forming the first and second semiconductor films includes forming first and second semiconductor films including silicon (Si); and,
wherein forming the insulator layer includes forming an insulator from a material selected from a group consisting of oxide films and nitride films.

7. The method of claim 1 wherein forming an opening in the insulator layer includes forming an opening in a first location; and,
wherein crystallizing the second semiconductor film includes controlling the grain boundaries of the crystallized second semiconductor film in response to the position of the first location.

8. The method of claim 1 wherein forming the first semiconductor film includes forming a bottom gate overlying the substrate;
wherein forming the insulator layer includes forming a bottom gate dielectric; and,
wherein forming the second semiconductor layer includes forming an active Si layer.

9. The method of claim 8 wherein forming the bottom gate includes forming a bottom gate with a first portion and a second portion;
wherein forming the opening in the insulator layer includes forming a via in the gate dielectric overlying the bottom gate first portion; and,
wherein partially melting the first semiconductor film includes melting the bottom gate first portion; and,
wherein using unmelted first semiconductor film as a seed includes using the bottom gate second portion as the seed for crystallizing the active Si layer.

10. The method of claim 8 wherein forming the active Si layer includes forming the active Si layer with a thickness in a range of about 500 Å to 1,500 Å.

11. The method of claim 9 further comprising:
subsequent to crystallizing the active Si layer, patterning the active Si layer to remove the active Si layer overlying vias in the gate dielectric.

12. The method of claim 11 further comprising:
forming a top gate overlying the active Si layer; and,
forming source/drain (S/D) regions in the active Si layer.

13. The method of claim 8 wherein forming the bottom gate overlying the transparent substrate includes forming the bottom gate overlying a transparent substrate selected from a group consisting of glass, plastic, and quartz.

14. The method of claim 8 wherein crystallizing the second semiconductor film includes laterally growing a crystal grain in the second semiconductor film having a length in the range of about 20 micrometers (μm) to 30 μm.

15. In a dual-gate thin-film transistor (DG-TFT), a method for seeding the crystallization of an active silicon (Si) layer using vias to an underlying bottom gate, the method comprising:
forming a Si bottom gate having a polycrystalline structure, overlying a transparent substrate;
forming an insulator layer overlying the bottom gate;
forming an opening in the insulator layer, exposing a portion of a bottom gate top surface;
forming an amorphous Si film overlying the insulator layer;
laser annealing the amorphous Si film;
in response to the laser annealing, completely melting the amorphous Si film and partially melting the bottom gate; and,
using an unmelted bottom gate polycrystalline structure as a seed, forming a polycrystalline Si active layer.

16. The method of claim 15 wherein laser annealing the amorphous Si film includes preheating the substrate with at least one laser fluence pulse from a first laser source, prior to melting the amorphous Si film with at least one laser fluence pulse from a second laser source.

17. The method of claim 15 wherein laser annealing includes laser annealing the amorphous Si film with a single Excimer laser pulse.

18. The method of claim 15 wherein forming the insulator layer includes forming a gate insulator from a material selected from a group consisting of oxide films and nitride films.

19. The method of claim 15 wherein forming the bottom gate includes forming a bottom gate with a first portion and a second portion;
wherein forming the opening in the insulator layer includes forming a via in a gate dielectric overlying the bottom gate first portion; and,
wherein partially melting the bottom gate includes melting the bottom gate first portion; and,
wherein using an unmelted bottom gate polycrystalline structure as a seed includes using the bottom gate second portion as the seed for crystallizing the active Si layer.

20. The method of claim 19 further comprising:
subsequent to forming the polycrystalline active Si layer, patterning the active Si layer to remove the active Si layer overlying vias in the gate dielectric;
forming a top gate overlying the active Si layer; and,
forming source/drain (S/D) regions in the active Si layer.
